(19) United States
(12) Patent Application Publication
(10) Pub. No.: US 2011/0012598 A1
(43) Pub. Date: Jan. 20, 2011

(54) MR COILS WITH AN ACTIVE ELECTRONIC COMPONENT HAVING AN INDIRECT POWER CONNECTION

(75) Inventors: Marinus Johannes Adrianus Maria van Helvoort, Best (NL); Johan Samuel van den Brink, Best (NL); Marc Paul Saes, Eindhoven (NL); Alexander Christiaan de Rijck, Eindhoven (NL); Klaas Jacob Lulofs, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/744,947

(22) PCT Filed: Nov. 27, 2008
(86) PCT No.: PCT/IB2008/054989

§ 371 Date: Sep. 3, 2010

(30) Foreign Application Priority Data
Nov. 30, 2007 (EP) 07121989.3

(51) Int. Cl. G01R 33/44

(52) U.S. Cl. 324/318

(57) ABSTRACT

A radio frequency coil comprises: a coil unit (30, 100) including one or more conductive radio frequency receive elements (32, 110) tuned to receive a magnetic resonance signal and an on-board active electronic component (34, 114, 118) operatively coupled with the one or more conductive radio frequency receive elements; and a power coupling element (40, 46, 134, 138, 140) configured to non-conductively receive electrical power from a power delivery element (44, 132, 136) during a magnetic resonance acquisition session to power the on-board active electronic component (114, 118) during the magnetic resonance acquisition session (e.g. wirelessly by inductive coupling or by capacitive coupling). In some embodiments, the power coupling element (134, 138, 140) is a component of the coil unit (102), and the radio frequency coil further comprises a base coil unit (104) including the power delivery element (132, 136) operatively combinable with the coil unit (102) to define an annular coil.

### FIELD OF THE INVENTION

The following relates to the magnetic resonance arts. The following finds illustrative application to magnetic resonance imaging, and is described with particular reference thereto. However, the following will find application in other magnetic resonance applications such as magnetic resonance spectroscopy.

### BACKGROUND OF THE INVENTION

Local magnetic resonance receive coils such as surface coils, torso coils, limb coils, or so forth typically include a conductive radio frequency reception element in the form of a conductive single-loop or multi-loop conductive element, an array of laterally spaced-apart (optionally partially overlapping) conductive loop elements, a conductive axial stripline element, or the like. Because the received magnetic resonance signal is generally weak, it is also known to include an on-board preamplifier in or with the local coil. Some magnetic resonance receive coils also include other on-board electronics such as analog-to-digital converters, optional signal multiplexors or combiners in the case of coil arrays, or so forth.

The preamplifier and perhaps some other optional on-board electronics (such as the optional analog-to-digital converter) are active electronics that require electrical power in order to operate. This power is generally supplied via conductive electrical power conductors that extend from the local coil, disposed on or in close proximity to the subject in the examination region, to a power supply located outside of the magnetic resonance scanner. Similarly, the received magnetic resonance signal is typically conveyed to the scanner via electrical signal conductors.

However, the connecting conductive cable or cables introduce a potential problem during the transmit phase. The RF-transmit field has a very high power compared with the magnetic resonance signal, and can induce currents in cables that connect the local receive coil with the magnetic resonance scanner.

In the case of data transmission cabling, one can suppress this effect by including detuning circuitry, or by using a wireless or fiber optic data transmission pathway. Such techniques are feasible for the low power levels involved in data transmission, although the radio frequency transmitter or semiconductor laser or other light signal launcher (in the case of a fiber optical link) adds additional on-board electrical power consumption to the local coil. However, fiber optics cannot be used efficiently for electrical power transmission, and wireless electrical power transmission has heretofore been problematic due to high losses encountered in transmitting sufficient electrical power into to the examination region so as to power the local coil.

Another known approach is to incorporate a cable trap into the power cabling. The cable trap is typically a radio frequency notch filter tuned to the magnetic resonance frequency to block unwanted induced common mode currents from flowing in the cable. The notch filter is generally effective, but can sometimes have its effectiveness reduced by shifts in the blocked frequency, introduced by cable movement or the particular positioning of the local cable for a particular subject or particular image acquisition. In general, the cable does not have a fixed position in the scanner and may be moved for each new subject. Accordingly, the cable trap does not ensure that the unwanted induced currents will not flow in the connecting cable. When a large induced current does flow, it can damage or destroy the coil or cause skin burns on the patient.

Another known approach is to provide on-board electrical power storage in or with the local coil in the form of a battery, storage capacitor, or the like. In some known embodiments, the battery or storage capacitor can be recharged when the stored electrical energy is depleted, for example at a recharging station using a wireless recharging connection or a suitable conductive recharger connector. However, batteries or storage capacitors can add substantial weight and bulk to the local coil, and can distort the local magnetic fields so as to interfere with magnetic resonance signal detection. Another problem with on-board electrical storage is the possibility that the stored electrical power may be exhausted before completion of an imaging session. Existing rechargeable batteries also have a limited number of recharging cycles, which can shorten the usable lifetime of the local coil or, alternatively, will entail occasional removal and replacement of the battery.

In some magnetic resonance applications, it is useful to have a local coil that surrounds the subject. Some examples of such coils include torso coils, limb coils, or so forth. For example, a typical torso coil includes lower and upper semiannular portions. The lower semiannular portion is mounted with the subject support. The patient lies down on the subject support, and the upper semiannular portion is attached to the lower semiannular portion to define an annular torso coil surrounding the patient's torso.

In a typical configuration for such a coil, the lower semiannular portion is mounted to the subject support underneath the subject. Accordingly, the lower semiannular portion is accessible for conductive electrical connection via the subject support. The upper semiannular portion is placed over the subject and conductively connects with the lower semiannular portion to receive electrical power and signal connections. Again, this conductive connection introduces concerns about current overloading during the transmit phase. Additionally, the conductive connectors are susceptible to damage and complicate sterilization of the local coil. These problems are exacerbated in multiple-element coils such as SENSE coils which have a large number of conductive connections.

The following provides new and improved apparatuses and methods which overcome the above-referenced problems and others.

### SUMMARY OF THE INVENTION

In accordance with one aspect, a radio frequency coil is disclosed, comprising: a coil unit including one or more conductive radio frequency receive elements tuned to receive a magnetic resonance signal and an on-board active electronic component operatively coupled with the one or more conductive radio frequency receive elements; and a power coupling element configured to non-conductively receive electrical power from a power delivery element during a magnetic resonance acquisition session to power the on-board active electronic component during the magnetic resonance acquisition session.

In accordance with another aspect, a power delivery element is configured to non-conductively couple with a coil unit including one or more conductive radio frequency receive elements tuned to receive a magnetic resonance signal, an on-board active electronic component operatively coupled with the one or more conductive radio frequency receive elements, a power coupling element disposed separately from the coil unit and proximate to the power delivery element, and a conductive cable conductively connecting the power coupling element with the coil unit. The power delivery element comprises an elongate element or an elongate array of elements arranged parallel with a side of a subject support.

In accordance with another aspect, a radio frequency coil is disclosed, comprising: a base coil unit including one or more base unit conductive radio frequency receive elements tuned to receive a magnetic resonance signal and a power delivery element; and a coil unit including one or more conductive radio frequency receive elements tuned to receive the magnetic resonance signal, an on-board active electronic component operatively coupled with the one or more conductive radio frequency receive elements, and a power coupling element configured to non-conductively receive electrical power from the power delivery element of the base coil unit to power the on-board active electronic component during a magnetic resonance acquisition session.

One advantage resides in efficient non-conductive power delivery, optionally in real time, to a local coil or local coil element.

Another advantage resides in reduced likelihood of subject injury or coil damage due to overloading during the transmit phase.

Another advantage resides in simplified electrical connection of a local coil.

Still further advantages of the present invention will be appreciated by those of ordinary skill in the art upon reading and understand the following detailed description.

### BRIEF DESCRIPTION OF THE DRAWINGS

These and other aspects will be described in detail hereinafter, by way of example, on the basis of the following embodiments, with reference to the accompanying drawings, wherein:

FIG. 1 diagrammatically shows a magnetic resonance scanner with a subject (shown in dashed lines) disposed on a subject support and operatively coupled with a local magnetic resonance receive coil;

FIG. 2 diagrammatically shows the local magnetic resonance receive coil of FIG. 1 with details of the non-conductive electrical power connection;

FIG. 3 diagrammatically shows a suitable embodiment of the non-conductive electrical power connection of FIG. 2, employing inductive transformer coupling, a conductive loop power coupling element, and an elongated solenoidal power delivery element;

FIG. 4 diagrammatically shows a suitable embodiment of the non-conductive electrical power connection of FIG. 2, employing a capacitive coupling, a capacitive plate power coupling element, and a power delivery element comprising an elongated array of capacitor plates;

FIG. 5 diagrammatically shows an annular local coil including upper and lower semiannular portions, with the upper and lower semiannular portions separated from one another for subject loading; and

FIG. 6 diagrammatically shows the annular local coil of FIG. 5, with the upper and lower semiannular portions positioned together for subject imaging.

### DETAILED DESCRIPTION OF EMBODIMENTS

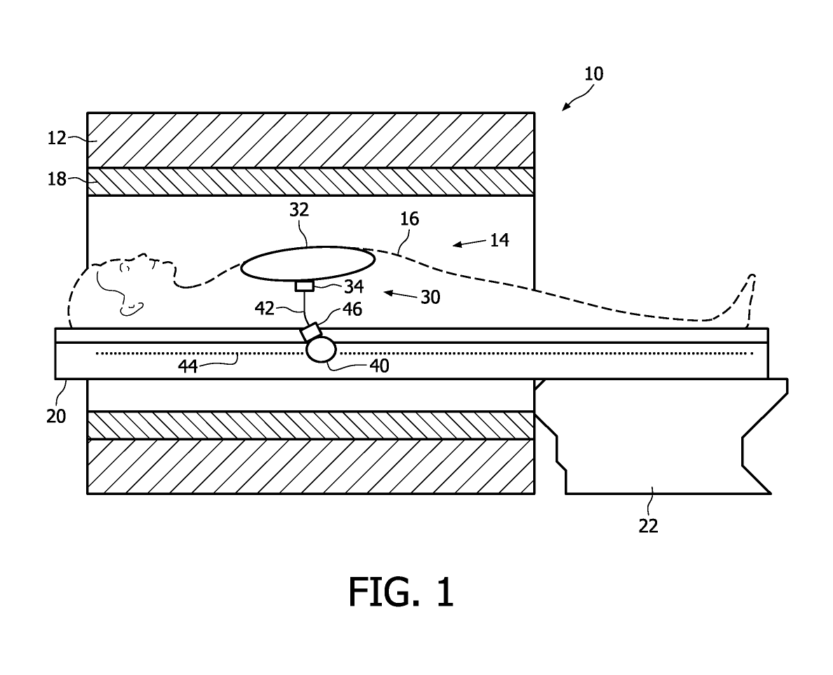

With reference to FIG. 1, a magnetic resonance scanner 10 includes a main magnet 12 generating a static main (B₀) magnetic field in an examination region 14 in which is disposed a subject 16 (shown in phantom in FIG. 1). The illustrated magnetic resonance scanner 10 is a horizontal bore-type scanner shown in cross-section to reveal selected components; however, other types of magnetic resonance scanners may be used such as vertical-magnet scanners, open-bore scanners, or so forth. The magnetic resonance scanner 10 also includes magnetic field gradient coils 18 that superimpose selected magnetic field gradients on the static (B₀) magnetic field to perform various tasks such as spatially restricting magnetic resonance excitation, spatially encoding magnetic resonance frequency and/or phase, spoiling magnetic resonance, or so forth. Optionally, the magnetic resonance scanner may include other elements not shown in FIG. 1, such as a birdcage, TEM, or other type of whole-body radio frequency coil for exciting and/or detecting magnetic resonance, a bore liner, active coil or passive ferromagnetic shims, or so forth. The subject 16 is suitably prepared by being placed on a movable subject support 20 which is then inserted along with the supported subject 16 into the illustrated position for magnetic resonance acquisition. For example, the subject support 20 may be a pallet or table that is initially disposed on a couch 22 adjacent the magnetic resonance scanner 10, the subject 16 placed onto the support 20 and then slidably transferred from the couch 22 into the bore of the magnetic resonance scanner 10.

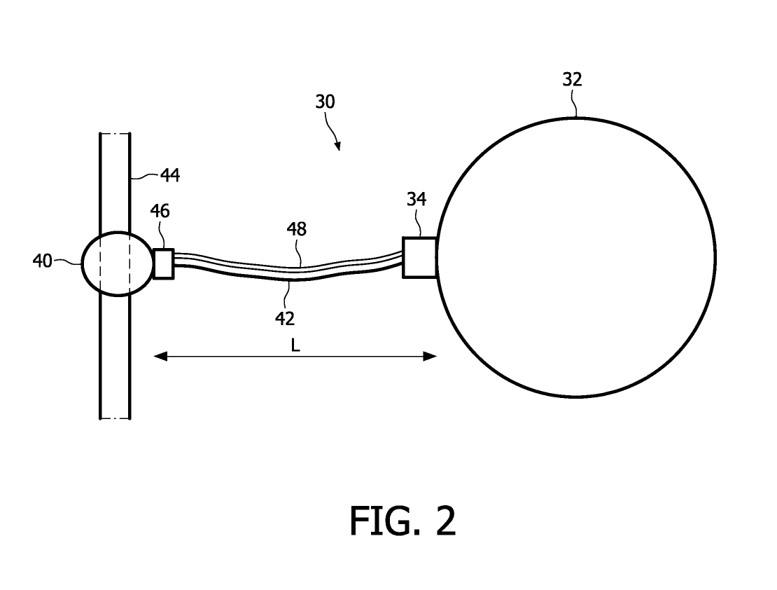

With continuing reference to FIG. 1 and with further reference to FIG. 2, a local coil 30 is disposed on the subject 16 for imaging. The illustrative local coil 30 includes a coil unit comprising a single-loop surface coil element 32 and an on-board active electronic component 34. While the illustrated embodiment employs the single-loop surface coil element as the conductive radio frequency receive element, it is to be appreciated that other radio frequency receive elements tuned to the magnetic resonance frequency may be used, such as an array of loop coil elements, a multi-loop coil element or array of such elements, a strip-line coil element or array of strip lines, or so forth. The on-board active electronic component 34 may, for example, comprise a printed circuit board supporting a preamplifier and optionally other electronics such as an analog-to-digital converter, detuning circuitry, or so forth.

The local coil 30 further includes a power coupling element 40 conductively connected with the coil unit by a conductive cable 42 having a length L. The power coupling element 40 is non-conductively coupled with a power delivery element 44, which in the illustrated embodiment is an elongated element or elongate array of elements arranged parallel with a side of the subject support 20 so as to enable the local coil 30 to be non-conductively connected with the power delivery element 44 at various points along the length of the subject support 20. In some embodiments, the non-conductive coupling is an inductive transformer coupling or a capacitive coupling—in such embodiments, the power received by the power coupling element 40 is A.C., and accordingly an A.C. to D.C. conversion is appropriate if the on-board active electronic component 34 draws D.C. power. The A.C.-to-D.C. conversion is suitably performed by an electronics module 46 of the power coupling element 40, or by A.C.-to-D.C. conversion circuitry of the on-board active electronic component 34.

The local coil 30 is not electrically connected by wires with the magnetic resonance scanner, and accordingly is electrically floating with respect to the magnetic resonance scanner. By avoiding wired electrical connections, complexity is reduced and reliability is increased, for example by elimination of mechanical couplings through the coil component housings. To reduce wireless radio frequency coupling, the conductive cable 42 should be relatively short compared with a wavelength of the magnetic resonance frequency. In some embodiments, the conductive cable 42 has a length less than or about one-quarter of a length of the wavelength of the magnetic resonance signal. However, a longer length for the conductive cable 42 is also contemplated, preferably in conjunction with radio frequency traps or other measures to reduce wireless radio frequency coupling.

The power coupling element 40 and conductive cable 42 provide a floating electrical power delivery system for delivering electrical power from the power delivery element 44 to the local coil 30. Additionally, the magnetic resonance signal detected by the local coil 30 should be transmitted to the magnetic resonance scanner in a manner which avoids wired electrical connections and consequent possible conduction at the magnetic resonance frequency. For example, in some embodiments the on-board active electronic component 34 includes a wireless transmitter for transmitting the magnetic resonance signal from the local coil 30. As another option, an optical fiber link 48 (shown only in FIG. 2) or inductive or capacitive coupling can be used to transmit the magnetic resonance signal from the local coil 30.

It is to be appreciated that the various components of the local coil 30 can be packaged in various ways. For example, the on-board active electronic component 34 may comprise two or more circuit boards with different electronics on each, or may comprise a single circuit board with multiple integrated circuit (IC) chips, or may include some discrete electronic components, or so forth. Although not shown, the coil unit including the conductive radio frequency receive element 32 tuned to receive a magnetic resonance signal and the on-board active electronics 34 may be disposed in or surrounded by an enclosure, housing, sealing, packaging, or so forth. The optical fiber 48, if included, is optionally sheathed together with the conductive cable 42. Other packaging arrangements and variations are also contemplated.

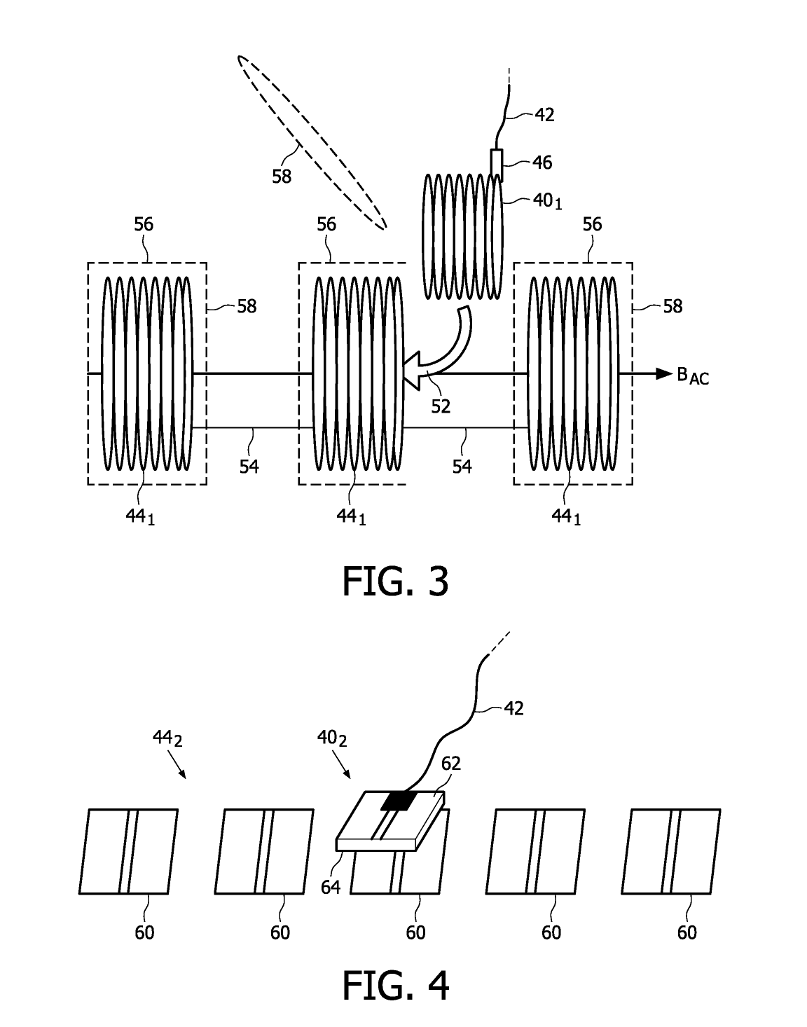

With continuing reference to FIGS. 1 and 2 and with further reference to FIG. 3, in some embodiments the power delivery element 44 is a series of solenoids 44₁ arranged in spaced apart fashion along the side of the subject support 20. The solenoids 44₁ are energized by an A.C. current to generate an alternating magnetic field B_{AC} located at least inside each solenoid 44₁ and directed parallel (or anti-parallel during the negative portion of the magnetic field cycle) with the axis of the solenoid 44₁. Such a solenoid wound at a sufficiently short helical pitch has little magnetic field leakage except possibly at the ends. Optionally, a surrounding, generally cylindrical, coaxial shield (not shown) can be provided to reduce magnetic field leakage still further. The power coupling element 40 in this illustrated embodiment has the form of a second solenoid loop 40₁ of smaller diameter than the power delivery element solenoids 44₁. For example, the illustration of FIG. 3 shows the power coupling element solenoid 40₁ in position to be inserted from the right into the middle power delivery element solenoid 44₁, as diagrammatically indicated by a curved arrow 52 in FIG. 3. Once inserted, the power coupling solenoid 40₁ has an A.C. current induced to flow in the solenoid by the alternating magnetic field B_{AC} passing through the area surrounded by the solenoid 40₁. This induced A.C. current effectuates electrical power transfer from the power delivery element 44₁ to the power coupling element 40₁ by inductive transformer action. The power delivery solenoids 44₁ can be individually powered, or can be connected in series by linking conductors 54 and powered by a single power connection (not shown). Optionally, traps (not shown) can be included with the linking conductors 54.

Because the power delivery element solenoids 44₁ generate A.C. magnetic fields, it is advantageous to magnetically shield the power delivery element solenoids 44₁ by a suitable shield, which in the illustrated embodiment comprises a can-shaped shield 56 surrounding each power delivery element solenoid 44₁, each shield 56 having a mating removable cap 58. To insert the power coupling element solenoid 40₁, the cap 58 is removed (as shown for the middle unit), the solenoid 40₁ inserted, and then the cap 58 is placed back onto the cylindrical shield 56 to complete the shielding. A small passthrough (not shown) in the shield 56, the cap 58, or the interface therebetween allows the conductive cable 42 of the inserted power coupling element solenoid 40₁ to extend out of the shield. In other embodiments, an elongate cylindrical shield (not shown) is contemplated to encompass all of the power delivery element solenoids 44₁ and to have removable sections to allow insertion of the power coupling element solenoid 40₁.

With continuing reference to FIGS. 1 and 2 and with further reference to FIG. 4, in an illustrative embodiment in which the non-conductive electrical power connection is capacitive in nature, the power delivery element 44 is in this case an elongate linear array 44₂ of capacitor plate pairs 60. The power coupling element 40 is in this embodiment a power coupling element 40₂ including a capacitor plate pair 62 with an insulating layer 64, such that when the insulating layer 64 is placed against one of the capacitor plate pairs 60 of the power delivery element 44₂, a capacitive power transfer coupling is formed. By applying A.C. power to the capacitor plates 60, electrical power is capacitively transferred to the power coupling element 40₂ to power the local coil 30. The power delivery element 44₂ can be held in place against the selected capacitor plate 60 by any suitable approach, such as an adhesive, a mechanical locking mechanism, a suitably configured slot into which the power delivery element 44₂ can fit, or so forth. Instead of having the insulating layer 64 of the capacitive coupling disposed as part of the power coupling element 40₂, it can instead or additionally be made part of the power delivery element 44₂, for example in the form of an insulating strip (not shown) covering the elongate linear array 44₂ of capacitor plates 60.

The arrangement of FIGS. 1-4 advantageously places the power delivery element 44 close to the local coil 30. The coil unit 32, 34 can have the same configuration as an ordinary wired local coil—the modification can be limited to the distal end of the power cable 42 away from the coil unit 32, 34. Both the local coil unit 32, 34 and the satellite power coupling element 40 can be positioned flexibly and in such a way that the power coupling element 40 is close to the power delivery element 44 to ensure efficient and effective power transfer. The close proximity between the power coupling element 40 and the power delivery element 44 ensures strong inductive or capacitive coupling, and hence efficient power transfer.

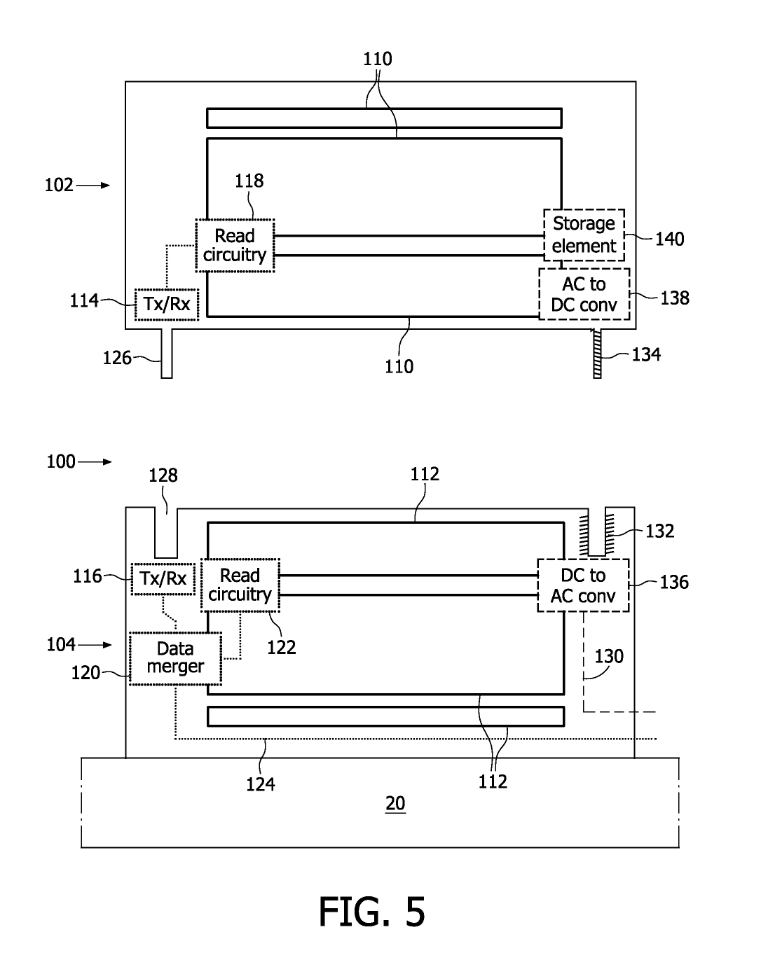

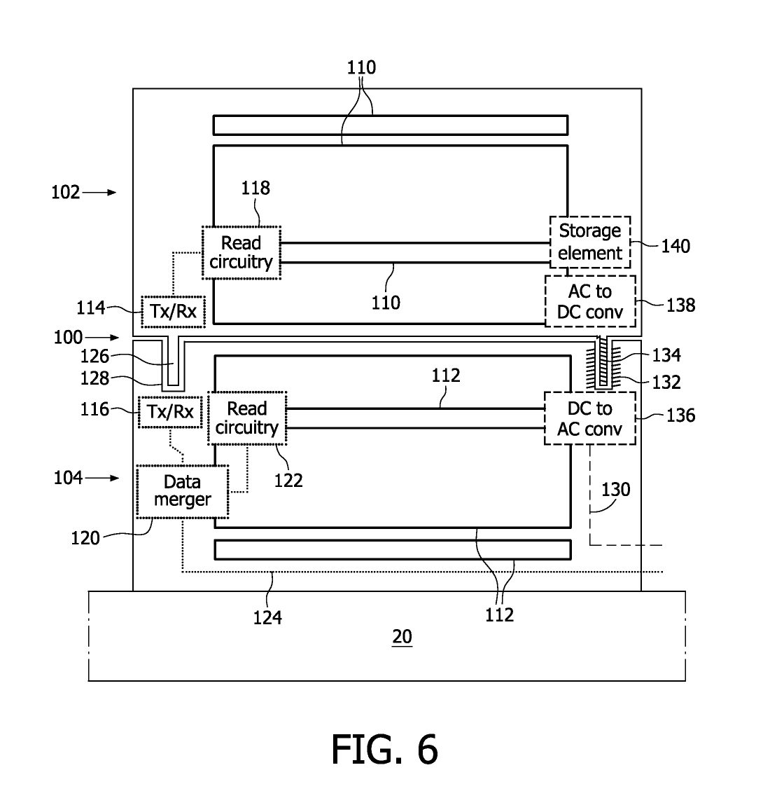

With reference to FIGS. 5 and 6, an illustrative generally annular local coil 100 is described. The term “annular” as used herein is intended to encompass any circular, oval, ring-shaped, loop-shaped, or similar configuration, and is intended to encompass such configurations having various cross-sections including circular, oval, square, rectangular, octagonal, or so forth. The local coil 100 is a splittable annular coil having a coil unit 102 that can be combined with or separated from a base coil unit 104. When separated, as shown in FIG. 5, a subject portion of interest such as a torso, limb, or so forth, and can be loaded between the coil units. In some embodiments, the base coil unit 104 is disposed on the subject support 20 (shown in part in FIGS. 5 and 6), and the subject is then disposed on top of the base coil unit 104. The coil units are then combined as shown in FIG. 6 to form the operative annular coil, for example by placing the coil unit 102 over the loaded subject to mate with the base coil unit 104. Other splittable coil configurations are also contemplated, such as a limb coil in which the base coil unit and the second coil unit are geometrically symmetric and neither is secured to the subject support, or a splittable coil in which the split is asymmetric such that the base coil unit and the second coil unit are not semiannular, or so forth.

FIGS. 5 and 6 diagrammatically show a side view of the local coil 100, with a transparent housing 102 to reveal internal components. Of course, opaque, translucent, semitranslucent, or other housings can also be used. The illustrated internal components include an array of spaced apart (optionally overlapping) conductive radio frequency receive elements tuned to receive a magnetic resonance signal, which in the illustrated embodiment are in the form of rectangular conductive loop elements 110 in the coil unit 102 and additional rectangular conductive loop elements 112 in the base coil unit 104. Selected electronic components are diagrammatically illustrated.

The local coil 100 is configured such that the coil unit 102 is electrically floating and does not have any wired electrical connection with the base coil unit 104 or with the subject support 20 or magnetic resonance scanner 10. To achieve this, the data communication link is wireless radio frequency, inductive, capacitive, or optical, employing read circuitry on the coil unit 102 and a suitable transmitter, receiver, or transceiver components 114, 116 disposed on the coil unit 102 and the base coil unit 104, respectively. The components 114, 116 may, for example, be opto-isolators employing LED or laser diode/photodiode pairs, or wireless radio frequency components. In the latter embodiments, the first and second communication linking elements 114, 116 optionally comprise a plurality of such paired elements defining separately shielded communication links all operating at the same frequency. Read circuitry 118 in the coil unit 102 processes the magnetic resonance signal received by the radio frequency receive elements 110, such processing optionally including various functionalities such as optional preamplification, optional digitization, or so forth. The processed signals are input to the communication linking element 114 for wireless or optical transmission to the communication linking element 116. A data merger unit 120 of the base coil unit 104 receives the signal from the coil unit 102 and a signal acquired by the radio frequency receive elements 112 and processed by read circuitry 122 of the base coil unit 104 to generate a final coil output signal that is output along a cable 124. In some embodiments, the wireless communication linkage includes mechanical mating elements that also aid in alignment of the coil units 102, 104, such as an illustrated pin 126 disposed on a surface of the coil unit 102 that mates with a hole 128 disposed on a mating surface of the base coil unit 104. For example, the pin 126 may include an optical fiber that illuminates a photodiode disposed in the recess of the hole 128 (for an opto-isolator coupling), or the pin 126 may include an inner conductor of a coaxial line and the hole 128 may be surrounded by the outer coaxial conductor to form an inductive coupling (for wireless radio frequency coupling).

In addition to magnetic resonance signals, the data coupling components 114, 116, 126, 128 optionally also provide communication of control signals, for example to cause the electrically floating coil unit 102 to operate detuning circuitry, to change an operational level of preamplification circuitry, or so forth.

Power is input to the base coil unit 104 via a power cable 130. To transfer power to operate the electronic components of the electrically floating coil unit 102, a power delivery element 132 disposed on or with the base coil unit 104 non-conductively transfers electrical power to a power coupling element 134 disposed on or with the electrically floating coil unit 102. In the illustrated embodiment, the power delivery element 132 is in the form of an outer inductive coil winding having a hollow opening that (when the coil units 102, 104 are operatively combined) receives the power coupling element 134 in the form of a pin including a coaxial coil winding so as to define an inductive transformer power coupling.

The input power on the power cable 130 may be either AC or DC. If the input power is DC, then a DC-to-AC converter 136 disposed in or with the base coil unit 104 converts the DC power to AC for application to the inductive power delivery element 132. Similarly, if the electronic components of the electrically floating coil unit 102 draw DC power, then an AC-to-DC converter 138 disposed in or with the coil unit 102 converts the received AC power to suitable DC power. Although an inductive power coupling is illustrated, a capacitive power coupling is also contemplated, which would again entail AC power being input to the power delivery element of the base coil unit and AC power output by the power coupling element of the electrically floating coil unit.

In some embodiments, the non-conductive power transfer elements 132, 134, 136, 138 operate in real time, that is, as magnetic resonance signals are being acquired, to provide real-time power to the electronic components of the coil unit 102 during the magnetic resonance acquisition. In these embodiments, the non-conductive power transfer occurs during a magnetic resonance acquisition session, and indeed even during the receive phase of a magnetic resonance pulse sequence. In such embodiments, there is optionally no battery, storage capacitor, or other electrical power storage device in the coil unit 102 configured to power the active electronic components 114, 118, since electrical power drawn by the electronic components 114, 118 is delivered “on demand” via the real-time power coupling. (It is to be appreciated that in such embodiments there may be storage capacitors or the like as circuit components of the electrical circuitry of the coil unit 102; however, such storage capacitors are not configured to power the active electronic components 114, 118). An issue which can arise in such embodiments is the possibility of radio frequency interference generated by the A.C. power transfer. To suppress such radio frequency interference, the frequency of the A.C. power being transferred can be selected to be at a frequency such that any generated radio frequency interference is unlikely to interfere with magnetic resonance acquisition. For example, the frequency of the A.C. power being transferred may be an integer multiple of the magnetic resonance scanner sampling frequency. Additionally or alternatively, radio frequency shielding (not shown) can be disposed around the components 132, 134, 136, 138 that carry A.C. current used in the A.C. power transfer coupling.

In some embodiments, it is contemplated to include a storage element 140 such as a storage capacitor or a storage battery in the electrically floating coil unit 102. In these embodiments, the non-conductive power transfer elements 132, 134, 136, 138 suitably operate to charge the optional storage element 140 when magnetic resonance data are not being acquired, and stop charging during acquisition to avoid producing radio frequency interference that might interfere with the magnetic resonance data acquisition. In other such embodiments, charging may be performed during the transmit phase and turned off during the receive phase. In some such embodiments, charging may be performed when no magnetic resonance pulse sequence is underway, and may be stopped during execution of a magnetic resonance pulse sequence (including transmit, receive, and any delay times). In any case, charging is suitably stopped if the storage element 140 is substantially fully charged. Charging can occur during a magnetic resonance acquisition session, that is, while the subject is loaded into the magnetic resonance scanner 10 for imaging or other magnetic resonance data acquisition. Charging can occur during intervals between pulse sequence executions or during the transmit phase in some embodiments. Because charging can occur during the magnetic resonance acquisition session, the storage element 140 does not need to hold a large charge over an extended period of time. Thus, a smaller, lighter, less bulky storage element can be used as compared with local coils that depend upon a battery that is recharged relatively infrequently at a remote recharging station. As another approach, the power transfer via the non-conductive power transfer elements 132, 134, 136, 138 can be performed continuously, and the coil portion 102 is operated by a combination of the transferred power and additional power supplied by the storage element 140. Again, this approach enables use of a smaller, lighter, less bulky storage element as compared with local coils that depend exclusively on a battery for operational power.

Unlike in some existing splittable coils, the annular local coil 100 does not have any coil loops that are split across the gap between the base coil unit 104 and the second coil unit 102. This advantageously eliminates the need for electrical contacts to bridge the split. The arrangement of the local coil 100 is feasible because the coil unit 102 is electrically floating and can be placed in close proximity with the base coil unit 104. The wireless electrical coupling can be made at the magnetic resonance frequency, e.g. by inductive or capacitive coupling. There is room in both the base coil unit 104 and the coil unit 102 to close the loops near the gap between the coil units 102, 104. In effect a single loop is broken into two electrically separate loops.

The invention has been described with reference to the preferred embodiments. Modifications and alterations may occur to others upon reading and understanding the preceding detailed description. It is intended that the invention be construed as including all such modifications and alterations insofar as they come within the scope of the appended claims or the equivalents thereof. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The disclosed method can be implemented by means of hardware comprising several distinct elements, and by means of a suitably programmed computer. In the system claims enumerating several means, several of these means can be embodied by one and the same item of computer readable software or hardware. The mere fact that certain measures are recited in mutually different dependent claims does not indicate that a combination of these measures cannot be used to advantage.

1. A radio frequency coil comprising:
a coil unit including one or more conductive radio frequency receive elements tuned to receive a magnetic resonance signal and an on-board active electronic component operatively coupled with the one or more conductive radio frequency receive elements; and
a power coupling element configured to non-conductively receive electrical power from a power delivery element during a magnetic resonance acquisition session to power the on-board active electronic component during the magnetic resonance acquisition session.

2. The radio frequency coil as set forth in claim 1, wherein the power delivery element is disposed in or with a subject support, the power coupling element is disposed separately from the coil unit and proximate to the power delivery element disposed in or with the subject support, and the radio frequency coil further includes:
a conductive cable conductively connecting the power coupling element with the coil unit.

3. The radio frequency coil as set forth in claim 1, wherein the power coupling element is disposed separately from the coil unit and proximate to the power delivery element, and the radio frequency coil further includes:
a conductive cable conductively connecting the power coupling element with the coil unit.

4. The radio frequency coil as set forth in claim 3, wherein the power coupling element and the power delivery element cooperatively define an inductive power transformer.

5. The radio frequency coil as set forth in claim 1, wherein the power coupling element is a component of the coil unit, the radio frequency coil further comprising:
a base coil unit operatively combinable with the coil unit to define an annular coil, the power delivery element being a component of the base coil unit such that the power coupling element is non-conductively coupled with the power delivery element when the coil unit and the base coil unit are operatively combined to define the annular coil.

6. The radio frequency coil as set forth in claim 5, wherein all power and data transfer between the coil unit and the base coil unit, when the coil unit and the base coil unit are operatively combined to define the annular coil, happens in a wireless manner.

7. The radio frequency coil as set forth in claim 5, wherein the power delivery element of the base coil unit includes a D.C.-to-A.C. converter that receives and converts D.C. power, and the power coupling element of the coil unit includes an A.C.-to-D.C. converter that converts non-conductively received A.C. power to D.C. power for the active electronic component.

8. The radio frequency coil as set forth in claim 5, wherein the power delivery element defines a first mechanical alignment element disposed on or in a surface of the base coil unit and the power coupling element defines a second mechanical alignment element disposed on or in a mating surface of the coil unit such that the first and second mechanical alignment elements at least contribute to mechanically aligning the coil unit and the base coil unit when the coil unit and the base coil unit are operatively combined to define the annular coil.

9. The radio frequency coil as set forth in claim 5, wherein the power coupling element and the power delivery element cooperatively define an inductive power transformer when the coil unit and the base coil unit are operatively combined to define the annular coil.

10. The radio frequency coil as set forth in claim 5, wherein the base coil unit and the coil unit include communication linking elements that non-conductively couple when the coil unit and the base coil unit are operatively combined to define the annular coil.

11. The radio frequency coil as set forth in claim 10, wherein first and second communication linking elements define a plurality of separately shielded communication links all operating at the same frequency.

12. The radio frequency coil as set forth in claim 1, wherein the coil unit is electrically floating with respect to the base coil unit and with respect to a magnetic resonance scanner performing the magnetic resonance acquisition session.

13. A power delivery element configured to non-conductively couple with a coil unit including one or more conductive radio frequency receive elements tuned to receive a magnetic resonance signal, an on-board active electronic component operatively coupled with the one or more conductive radio frequency receive elements, a power coupling element disposed separately from the coil unit and proximate to the power delivery element, and a conductive cable conductively connecting the power coupling element with the coil unit, the power delivery element comprising:
an elongate element or an elongate array of elements arranged parallel with a side of a subject support.

14. The power delivery element as set forth in claim 13, wherein the power coupling element of the coil unit includes an inductive element, and the power delivery element comprises:
an elongate solenoid arranged parallel with the side of the subject support and configured to inductively couple with the inductive element of the coil unit at any selected one of a plurality of locations along the elongate solenoid.

15. The power delivery element as set forth in claim 13, wherein the power coupling element of the coil unit includes a capacitive element, and the power delivery element comprises:
a linear array of capacitive elements arranged parallel with the side of the subject support, the capacitive element of the coil unit being configured to capacitively couple with any selected one of the capacitive elements of the linear array of capacitive elements.
